(19) United States
(12) Patent Application Publication
(10) Pub. No.: US 2004/0164223 A1
(43) Pub. Date: Aug. 26, 2004

(54) Automatic object plane selection in an optical image scanner

(76) Inventor: Rodney C. Harris, Fort Collins, CO (US)

Correspondence Address: HEWLETT-PACKARD DEVELOPMENT COMPANY, Intellectual Property Administration, P.O. Box 272400, Fort Collins, CO, 80527-2400, US

(21) Appl. No.: 10/370,675

(22) Filed: Feb. 20, 2003

(51) Int. Cl. H01L 27/00

(52) U.S. Cl. 250/208.1

(57) ABSTRACT

Automatic object plane selection in an optical image scanner is provided. One embodiment is a method for optically scanning a document comprising generating a scanned image of a document at a first object plane located a first distance above a platen, generating a scanned image of the document at a second object plane located a second distance above the platen, and automatically determining which of the scanned images has better image quality.

### BACKGROUND

Optical image scanners, also known as document scanners, convert a visible image (e.g., on a document or photograph, an image in a transparent medium, etc.) into an electronic form suitable for copying, storing, or processing by a computer. An optical image scanner may be a separate device, or an image scanner may be a part of a copier, part of a facsimile machine, or part of a multipurpose device. Reflective image scanners typically have a controlled source of light, and light is reflected off the surface of a document, through an optics system, and onto an array of photosensitive devices (e.g., a charge-coupled device, complimentary metal-oxide semiconductor (CMOS), etc.). Transparency image scanners pass light through a transparent image, for example a photographic positive slide, through optics, and then onto an array of photosensitive devices. The optics focus at least one line, called a scanline, of the image being scanned, onto the array of photosensitive devices. The photosensitive devices convert received light intensity into an electronic signal. An analog-to-digital converter converts the electronic signal into computer readable binary numbers, with each binary member representing an intensity value.

There are two common types of image scanners. In a first type, a single spherical reduction lens system is commonly used to focus the scanline onto the photosensor array, and the length of the photosensor array is much less than the length of the scanline. In a second type, an array of many lenses is used to focus the scanline onto the photosensor array, and the length of the photosensor array is the same length as the scanline. For the second type, it is common to use Selfoc® lens arrays (SLA) (available from Nippon Sheet Glass Co.), in which an array of rod-shaped lenses is used, typically with multiple photosensors receiving light through each individual lens.

Depth of focus refers to the maximum distance that the object position may be changed while maintaining a certain image resolution (i.e., the amount by which an object plane may be shifted along the optical path with respect to some reference plane and introduce no more than a specified acceptable blur). The depth of focus for lens arrays is typically relatively short in comparison to scanners using a single spherical reduction lens system. Typically, flat documents are forced by a cover against a transparent platen for scanning, so depth of focus is not a problem. However, there are some situations in which the surface being scanned cannot be placed directly onto a platen. One example is scanning 35 mm slides. A typical frame for a 35 mm slide holds the surface of the film about 0.7-1.5 mm above the surface of the platen. As a result, slides may be slightly out of focus when using lens arrays that are focused at the surface of the platen. Another example is scanning books or magazines where part of a page being scanned curves into a binding spline, causing part of the surface being scanned to be positioned above the transparent platen. A large depth of focus is needed to sharply image the binding spline.

### SUMMARY

Embodiments of the present invention provide automatic object plane selection in an optical image scanner.

One embodiment is a method for optically scanning a document comprising generating a scanned image of a document at a first object plane located a first distance above a platen, generating a scanned image of the document at a second object plane located a second distance above the platen, and automatically determining which of the scanned image has better image quality.

Another embodiment is an optical image scanner comprising a platen, an optical head configured to scan at a first object plane located a first distance above the platen and at a second object plane located a second distance above the platen, logic configured to generate a scanned image of the document at the first object plane, logic configured to generate a scanned image of the document at the second object plane, and logic configured to determine which of the scanned images has better image quality.

Yet another embodiment of an optical image scanner comprises a means for generating a scanned image of the document at a first object plane located a first distance above a platen, a means for generating a scanned image of the document at a second object plane located a second distance above the platen, and a means for determining which of the scanned images has better image quality.

### BRIEF DESCRIPTION OF THE DRAWINGS

Many aspects of the invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1 is a block diagram of a cross-sectional view of an embodiment of an optical image scanner including an automatic object plane selection system according to the present invention.

FIG. 2 is a block diagram of a cross-sectional view of another embodiment of an optical image scanner including an automatic object plane selection system according to the present invention.

FIG. 3 is a block diagram of a cross-sectional view of a further embodiment an optical image scanner including an automatic object plane selection system according to the present invention.

FIG. 4 is a flowchart illustrating the architecture, operation, and/or functionality of an embodiment of the automatic object plane selection system, such as is shown in FIGS. 1-3.

FIG. 5 is a flowchart illustrating the architecture, operation, and/or functionality of another embodiment of the automatic object plane selection system, such as is shown in FIG. 1-3.

FIG. 6 is a block diagram of a top view of an optical image scanner, such as is shown in FIGS. 1-3.

FIG. 7 is a block diagram of an optical image scanner, such as is shown FIGS. 1-3, which illustrates one of a number of implementations of an automatic object plane selection system.

### DETAILED DESCRIPTION

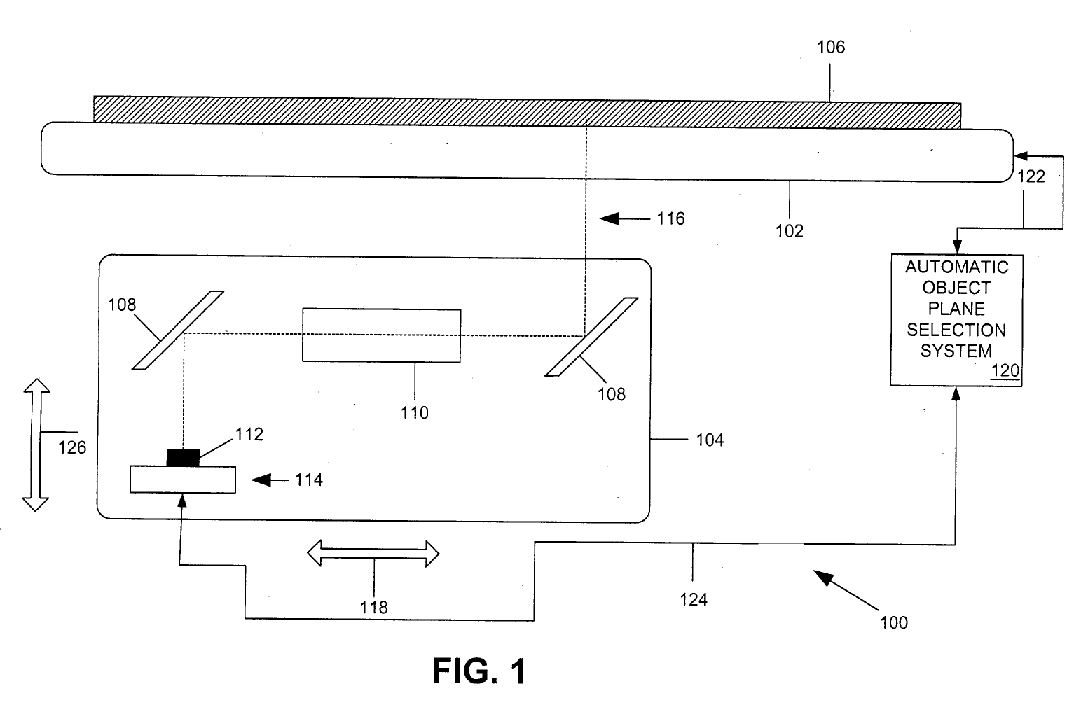

FIG. 1 is a block diagram of a cross-sectional view of an optical image scanner 100 including an automatic object plane selection system 120 according to the present invention. The architecture, operation, and functionality of various embodiments of automatic object plane selection system 120 is described below in detail. However, by way of introduction, the general architecture, operation, and functionality will be briefly described. In general, automatic object plane selection system 120 enables an object 106 to be automatically scanned at multiple object planes above platen 102. Automatic object plane selection system 120 determines which object plane generates an image with better image quality. For example, instead of a user having to adjust for variations in the height above platen 102 when scanning a portable target 106 (e.g., document, paper, negatives, transparency, 35 mm slides, magazines, books, etc.), automatic object plane selection system 120 automatically analyzes the digital images corresponding to each object plane and determines the digital image having the best image quality. Thus, automatic object plane selection system 120 automatically selects an appropriate object plane.

The relative sizes of various objects in FIG. 1 are exaggerated to facilitate illustration. As shown in FIG. 1, optical image scanner 100 comprises an optical head 104 (also known as a carriage) positioned relative to a transparent platen 102. As known in the art, a document 106 may be placed on the top surface of the platen 102 for scanning. Optical image scanner 100 may be included within an optical image scanner (e.g., a low profile flatbed scanner), a facsimile machine, copier, etc.

As further illustrated in FIG. 1, optical head 104 comprises a first reflective surface 108 (e.g., mirror, etc.), a lens array 110, a second reflective surface 108, and an image sensor module 114. Image sensor module 114 may comprise, for example, a printed circuit assembly or any other semiconductor device. Image sensor module 114 also includes a photosensor array 112, which may be any type of device configured to receive optical signals and convert the light intensity into an electronic signal. For example, as known in the art, photosensor array 112 may comprise a charge-coupled device (CCD), complimentary metal-oxide semiconductor (CMOS), etc.

Lens array 110 may comprise an array of rod-shaped lenses which have a relatively short depth of focus. For example, lens array 110 may comprise a Selfoc® lens array (SLA), which is manufactured and sold by Nippon Sheet Glass Co. of Somerset, N.J. A rod-lens array may comprise at least one row of graded-index micro lenses, which may be equal in dimensions and optical properties. The lenses may be aligned between two fiberglass-reinforced plastic (FRP) plates. Because FRP has a coefficient of thermal expansion equal to glass, thermal distortion and stress effects are minimal. The FRP also increases mechanical strength of the SLA. The interstices may be filled with black silicone to prevent flare (crosstalk) between the lenses and protect each individual lens.

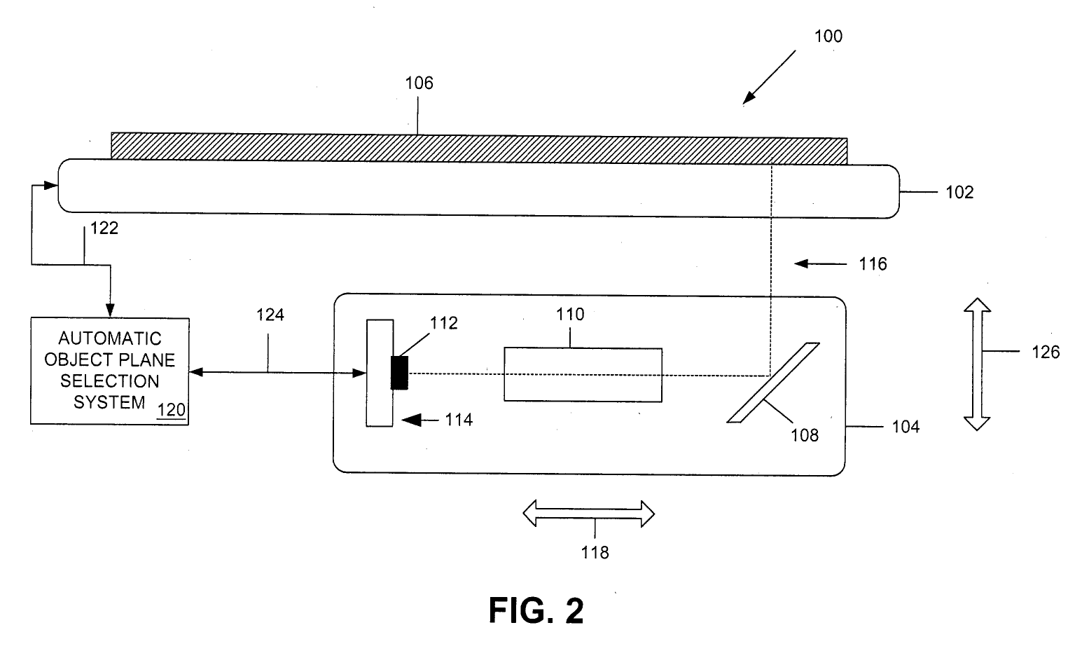

Referring again to FIG. 1, as a document 106 is being scanned by optical head 104, an optical signal 116 is reflected off the document 106 and towards the first reflective surface 108. The first reflective surface 108 directs the optical signal 116 through the lens array 110 to be focused. The optical signal 116 may also be reflected toward image sensor module 114 by a second reflective surface 108. The optical signal 116 is received by photosensor array 112 and converted into an electronic signal, which may be processed by an analog-to-digital converter, digital signal processor, etc. In this manner, the optics within optical head 104 focus a portion of an image of document 106 onto photosensor array 112. As illustrated in FIG. 2, the second reflective surface 108 may be optional. For instance, in order to alter the cross-sectional profile of optical head 104, second reflective surface 108 may be removed and the image sensor module 114 may be oriented perpendicular to the optical axis of lens array 110 to receive optical signal 116. Alternatively, the optical axis of lens array 110 may be oriented perpendicular to platen 102 to direct light through lens array 110 and onto photosensor array 112. The particular orientation of lens array 110 is not relevant to the present invention.

The optical components within optical head 104 focus at least one line (i.e., a scanline) of the image being scanned onto photosensor array 112. As known in the art, scanning of the entire image may be accomplished by translating optical head 104 relative to document 106 (e.g., by using cables) as indicated by reference number 118. As described in more detail below, optical image scanner 100 also comprises at least one mechanism for adjusting the object plane to be scanned. For example, some mechanisms may adjust the location of the object plane by adjusting optical head 104 relative to platen 102 (as indication by reference number 126).

As mentioned above, due to the relatively small depth of focus of lens array 110, existing optical image scanners may produce blurred images of documents 106 that are positioned a small distance above/below the primary focal point of lens array 110. For example, existing optical image scanners may be configured with the primary focal point at a relatively short distance Ho above the top surface of platen 102. When a document 106, such as a sheet of paper, etc. is positioned on platen 102, it may be located approximately the distance H₀ above the top surface of platen 102 or within the relatively small range of the depth of focus. However, if the document 106 is positioned at an object plane that is outside of a range of acceptable focus, existing optical image scanners may produce a blurred image. For instance, various types of documents (or portions of the document) may be located at an object plane outside of the range of acceptable focus when positioned on platen 102 (e.g., 35 mm slides, transparencies, photographs, books, magazines, etc.).

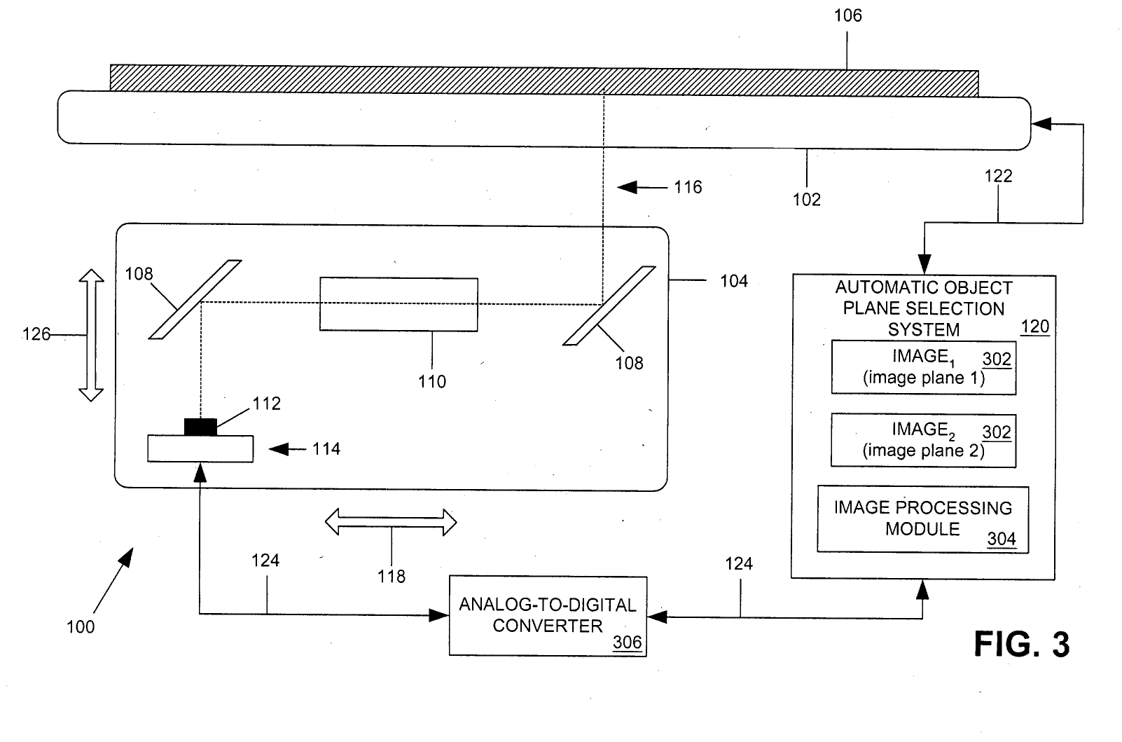

Having described a general overview of an optical image scanner 100, various systems and methods according to the present invention for providing automatic object plane selection will be described with respect to FIGS. 3-7. FIG. 3 is a block diagram of a cross-sectional view of an embodiment of optical image scanner 100. As illustrated in FIG. 3, optical image scanner 100 further comprises an analog-to-digital converter 306 in communication with image sensor module 114 via interface 124. As stated above, image sensor module 114 may be configured to receive light and convert the light intensity into an electronic signal. In this regard, analog-to-digital converter 306 is configured to convert the analog signals into a digital format. As known in the art, the digital signals may be processed to generate a digital image.

Optical image scanner 100 further comprises automatic object plane election system 120 according to the present invention. As stated above, automatic object plane selection system 120 enables a document 106 to be automatically scanned at multiple object planes above platen 102 to determine which object plane generates an image with better image quality. Stated another way, automatic object plane selection system 120 determines which scanned object plane generates the best image quality. Thus, it should be appreciated that optical image scanner 100 further comprises at least one mechanism for scanning document 106 at multiple object planes above platen 102.

The particular mechanism for scanning multiple object planes is not relevant for implementation of automatic object plane selection system 120. However, it should be appreciated that optical image scanner 100 is configured to scan at multiple object planes above platen 102 and generate at least two corresponding digital images. Nonetheless, various object plane adjustment mechanisms will be briefly discussed. One of ordinary skill in the art will appreciate that these, and various other, systems and methods may be employed.

As stated above, optical image scanner 100 may include several types of mechanisms for adjusting the location of the object plane by adjusting the distance between optical head 104 and platen 102. One of many examples is described in commonly-assigned U.S. patent application Ser. No. 09/919,008, entitled “Optical Image Scanner With Adjustable Focus” and filed Jul. 31, 2001, which is hereby incorporated by reference in its entirety.

Other mechanisms for adjusting the distance between optical head 104 and platen 102 may be employed. For example, the object plane adjustment mechanism may be integrated with the mechanism that translates optical head 104 along the axis identified by reference numeral 118. Various mechanical means may be employed to adjust the distance between optical head 104 and platen 102 as the optical head is translated. Several examples are described in the following commonly-assigned and mutually-filed U.S. patent applications, which are each incorporated by reference in its entirety: U.S. patent application Ser. No. ______, entitled “End-of-Travel Focus Shift in an Optical Image Scanner;” and U.S. patent application Ser. No. ______, entitled “End-of-Travel Focus Shift in an Optical Image Scanner.”

The location of the object plane above platen 102 may also be adjusted without having to reposition optical head 104 relative to platen 102. Instead of moving optical head 104, multiple object planes may be provided by modifying the internal optics of optical head 104. In this regard, optical head 104 may remain fixed relative to platen 102, while the internal optics are configured to provide multiple object planes (i.e., primary focal point at various distances above the top surface of platen 102).

In one embodiment, the location of the object plane above platen 102 may be adjusted by pivoting/moving a reflective surface 108. One example is described in commonly-assigned and mutually-filed U.S. patent application Ser. No. ______, entitled “Systems and Methods for Providing Multiple Object Planes in an Optical Image Scanner,” which is hereby incorporated by reference in its entirety. The object plane may also be adjusted by pivoting/moving image sensor module 114.

In further embodiments, the location of the object plane above platen 102 may be adjusted by providing at least two photosensor arrays 112 on image sensor module 114 (i.e., a first photosensor array 112 for a first object plane and a second photosensor array 112 for a second object plane). The position of one photosensor array 112 may be shifted relative to the other photosensor array 112. It will be appreciated that the differential in the optical path lengths between each photosensor array 112 and lens array 110 provides a proportional differential in the corresponding object planes. Several examples are described in commonly-assigned and mutually-filed U.S. patent application Ser. No. ______, entitled “Systems and Methods for Providing Multiple Object Planes in an Optical Image Scanner,” which is hereby incorporated by reference in its entirety.

In a further embodiment, optical image scanner 100 may be configured with at least two lens arrays 110 and corresponding photosensor arrays 112. Each lens array 110 and corresponding photosensor array 112 (i.e., lens array 110/photosensor array 112 pair) may be disposed in optical head 104 so that the photosensor array 112 is located at a unique object plane relative to platen 102. Several examples are described in commonly-assigned and mutually-filed U.S. patent application Ser. No. ______, entitled “Systems and Methods for Providing Multiple Object Planes in an Optical Image Scanner,” which is hereby incorporated by reference in its entirety.

In additional embodiments, multiple object planes relative to platen 102 may be provided by changing the effective distance of one optical path (between lens array 110 and photosensor array 112) relative to the other optical path (e.g., by inserting an optical delay element along one optical path, implementing a beam splitter, etc.). Several examples are described in commonly-assigned and mutually-filed U.S. patent application Ser. No. ______, entitled “Systems and Methods for Providing Multiple Object Planes in an Optical Image Scanner,” which is hereby incorporated by reference in its entirety.

Regardless of the particular object plane adjustment mechanism employed, it should be appreciated that at least two digital images 302 (FIG. 3) are generated—one digital image 302 at the first object plane and another digital image 302 at the second object plane. In this regard, automatic object plane selection system 120 is configured to determine which of the scanned digital images 302 has better image quality (e.g., via image processing modules(s) 394, etc.).

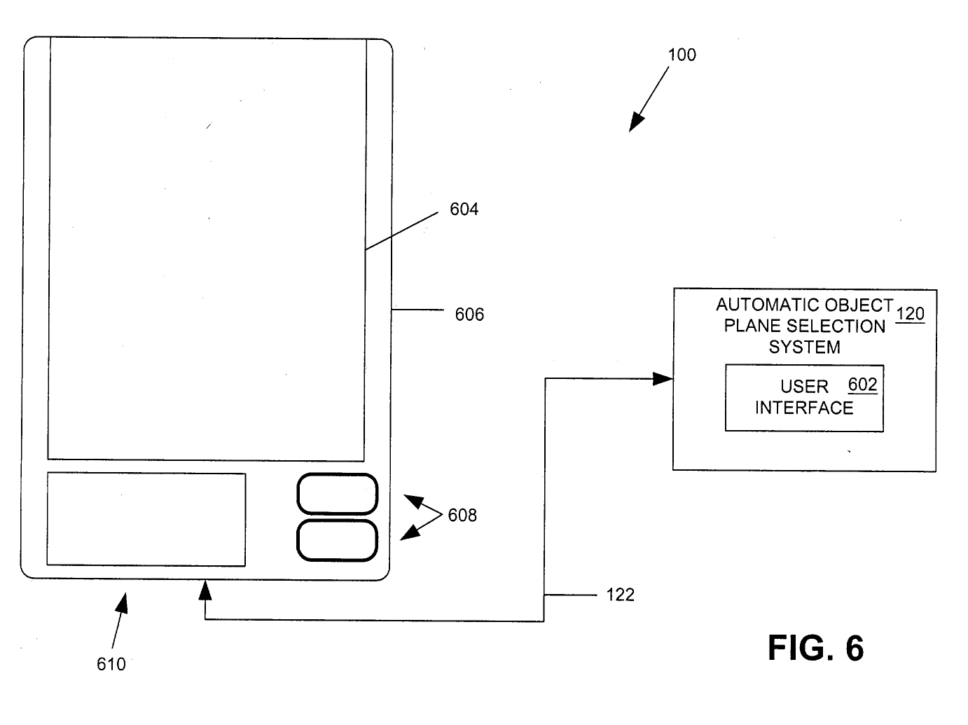

As further illustrated in FIG. 3, automatic object plane selection system 120 communicates with image sensor module 114 via interface 124 and analog-to-digital converter 306. Automatic object plane selection system 120 may also communicate with various user controls (FIG. 6) via interface 122.

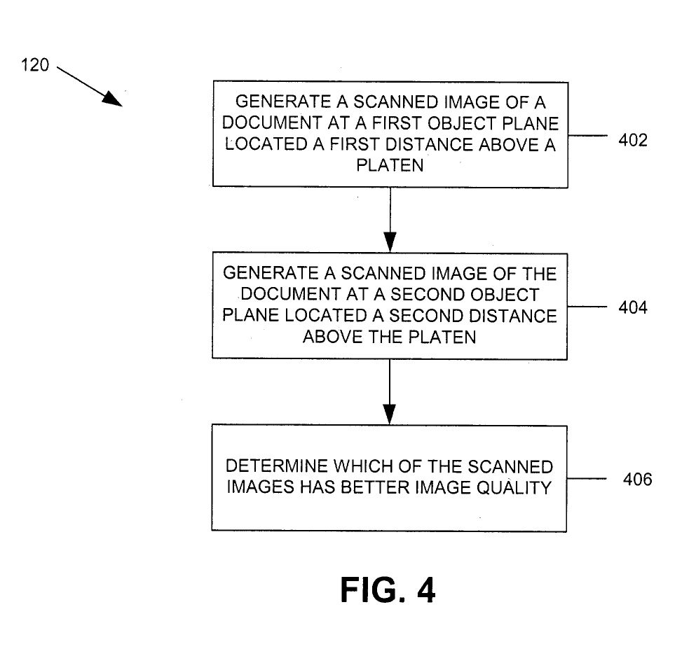

FIG. 4 is a flowchart illustrating the general architecture, operation, and/or functionality of an embodiment of automatic object plane selection system 4120 according to the present invention. At block 402, automatic object plane selection system 120 generates a scanned digital image 302 at a first object plane located a first distance above platen 102. Such a digital image 302 may be generated using any of the modalities described above or others. Furthermore, the scanned digital image 302 may be stored and made accessible to automatic object plane selection system 120 (FIG. 3).

At block 404, automatic object plane selection system 120 generates a scanned digital image 302 at a second object plane located a second distance above platen 102. Such digital image 302 may also be generated using any of the modalities described above, or others. Furthermore, the scanned digital image 302 may be stored and made accessible to automatic object plane selection system 120. It should be appreciated that the object planes may be simultaneously scanned. Alternatively, the object planes may be scanned at different times, with different modalities, etc. It should be further appreciated that a document 106 may be scanned at more than two object planes. Therefore, at least two digital images 406 are generated.

After the digital images 302 are generated, at block 406, automatic object plane selection system 120 determines which of the digital images 302 has a better image quality (i.e., select the object plane above platen 102 that produces the best image quality). For example, automatic object plane selection system 120 may employ one or more image processing algorithms (e.g., image processing module 304) to determine the image quality of each digital image 302.

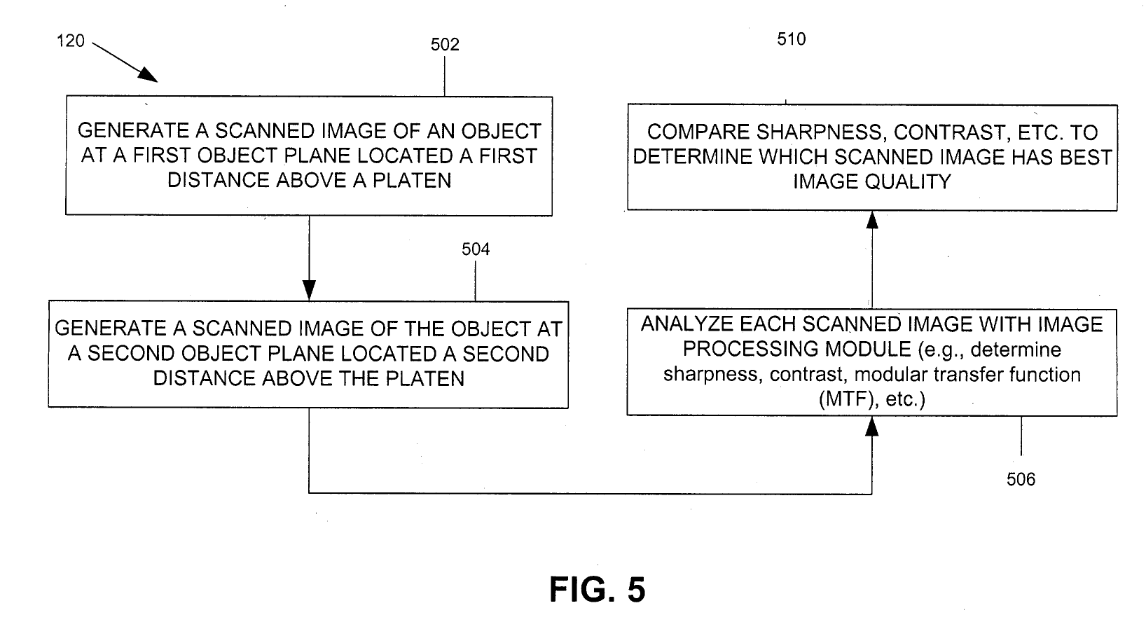

Referring to the embodiment illustrated in FIG. 5, at block 506, automatic object plane selection system 120 analyzes the digital images 302 with image processing module 304. As known in the art, the quality of a digital image 302 may be determined based on a variety of image quality parameters. For instance, automatic object plane selection system 120 may determine the sharpness, contrast, etc. of the particular image. Alternatively, automatic object plane selection system 120 may employ any of a variety of auto-focus algorithms. At block 510, automatic object plane selection system 120 compares the image quality parameters to determine which digital image 302 has the best quality. In this manner, automatic object plane selection system 120 determines which object plane (i.e., location above platen 102) produces the higher quality digital image.

Referring to FIGS. 4 and 5, it should be appreciated that the functions represented by the numbered blocks may be performed in many different orders. Furthermore, some functions may be performed at substantially the same time, concurrently, etc.

It should be appreciated that the relative image quality of digital images 302 may be determined in a variety of other ways. For example, referring to FIG. 6, automatic object plane selection system 120 may be further configured with a user interface 602 to enable a user to select which digital image 302 to use. Thus, automatic object plane selection system 120 may be configured to display each of the scanned digital images 302 to the user. Based on the relative visual appearances of the digital images 302, the user may select which digital image has the better image quality. Thus, automatic object plane selection system 120 may also be configured to receive the user selection.

In this regard, as illustrated in FIG. 6, optical image scanner 100 comprises a housing 606 in which optical head 104 and automatic object plane selection system 120 reside. As known in the art, optical image scanner 100 may further comprise a hinged platen cover 604. During operation, a user may lift platen cover 604 to position an object 106 on platen 102. Optical image scanner 100 may further comprise various types of user controls (e.g., electronic display 610, selection buttons 608, etc.) that are configured to enable the user to specify which digital image 302 has the better image quality. As illustrated in FIG. 6, automatic object plane selection system 120 may communicate with the user controls via interface 122. It should be appreciated that, depending on the particular complexity of user interface 602, various other user controls may be used.

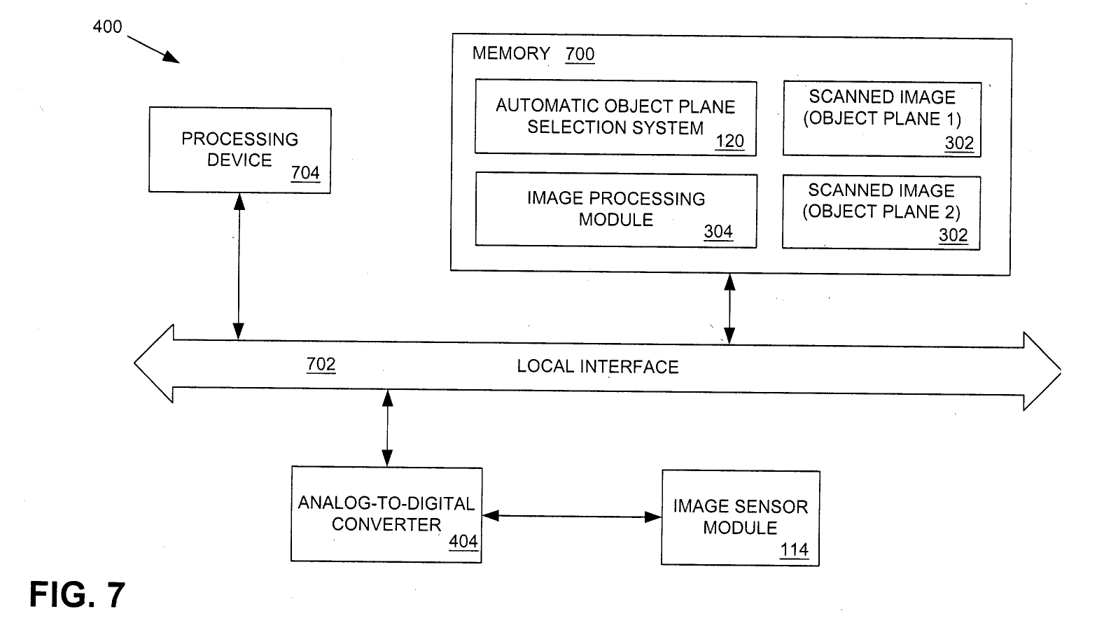

FIG. 7 is a block diagram of optical image scanner 100 illustrating one of a number of embodiments for implementing automatic object plane selection system 120. Optical image scanner 100 may comprise a processing device 404, memory 700, one or more input/output (I/O) devices (e.g., electronic display 610, buttons 608, etc.), optical head 104, translation mechanism 118, and optical head adjustment mechanism 120, each of which is connected to a local interface 702.

The processing device 704 can include any custom made or commercially-available processor, a central processing unit (CPU) or an auxiliary processor among several processors associated with optical image scanner, a semiconductor based microprocessor (in the form of a microchip), a macroprocessor, one or more application-specific integrated circuits (ASICs), a plurality of suitably-configured digital logic gates, and other well known electrical configurations comprising discrete elements both individually and in various combinations to coordinate the overall operation of optical image scanner 100.

The memory 700 can include any one of a combination of volatile memory elements and nonvolatile memory elements. The memory 700 includes automatic object plane selection system 120. One of ordinary skill in the art will appreciate that the memory 700 may comprise other components which have been omitted for purposes of brevity.

It should be appreciated that automatic object plane selection system 120 may be implemented in hardware, software, firmware, or any combination thereof. It is to be understood that this logic can be stored on any computer-readable medium for use by or in connection with any computer-related system or method. In the context of this document, a computer-readable medium denotes an electronic, magnetic, optical, or other physical device or means that can contain or store a computer program for use by or in connection with a computer-related system or method. These programs can be embodied in any computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any means that can store, communicate, propagate, or transport the program for use by or in connection with the instruction execution system, apparatus, or device.

The computer-readable medium can be, for example but not limited to, an electronic, magnetic, optical, electromagnetic, infrared, or semiconductor system, apparatus, device, or propagation medium. Note that the computer-readable medium can even be paper or another suitable medium upon which a program is printed, as the program can be electronically captured, via for instance optical scanning of the paper or other medium, then compiled, interpreted or otherwise processed in a suitable manner if necessary, and then stored in a computer memory.

Therefore, having thus described the invention, at least the following is claimed:

1. A method for optically scanning a document, the method comprising:
generating a scanned image of a document at a first object plane located a first distance above a platen;
generating a scanned image of the document at a second object plane located a second distance above the platen; and
automatically determining which of the scanned images has better image quality.

2. The method of claim 1, wherein determining which of the scanned images has better image quality comprises analyzing the scanned images with an image processing algorithm.

3. The method of claim 1, wherein determining which of the scanned images has better image quality comprises determining at least one of a sharpness parameter and a contrast parameter for each scanned image.

4. The method of claim 1, wherein determining which of the scanned images has better image quality comprises:
displaying both scanned images to a user; and
receiving a user selection of one of the scanned images.

5. An optical image scanner comprising
a platen;
an optical head configured to scan a first distance above the platen and at a second object plane located a second distance above the platen;
logic configured to generate a scanned image of the document at the first object plane;
logic configured to generate a scanned image of the document at the second object plane; and
logic configured to determine which of the scanned images has better image quality.

6. The optical image scanner of claim 5, wherein the logic configured to determine which of the scanned images has better image quality comprises logic configured to analyze the scanned images with an image processing algorithm.

7. The optical image scanner of claim 5, wherein the logic configured to determine which of the scanned images has better image quality comprises logic configured to determine at least one of a sharpness parameter and a contrast parameter for each scanned image.

8. The optical image scanner of claim 5, wherein the logic configured to determine which of the scanned images has better image quality comprises:
logic configured to display both scanned images to a user; and
logic configured to receive a user selection of one of the scanned images.

9. The optical image scanner of claim 5, further comprising a processing device configured to implement the logic.

10. An optical image scanner comprising:
a means for generating a scanned image of the document at a first object plane located a first distance above a platen;
a means for generating a scanned image of the document at a second object plane located a second distance above the platen; and
a means for determining which of the scanned images has better image quality.

11. The optical image scanner of claim 10, wherein the means for determining which of the scanned images has better image quality comprises an image processing means.

12. The optical image scanner of claim 10, wherein the means for determining which of the scanned images has better image quality comprises:
a means for displaying both scanned images to a user; and
a means for receiving a user selection of one of the scanned images.

13. A computer program embodied in a computer-readable medium comprising:
logic configured to generate a scanned image of the document at the first object plane;
logic configured to generate a scanned image of the document at the second object plane; and
logic configured to automatically determine which of the scanned images has better image quality.

14. The computer program of claim 13, wherein the logic configured to determine which of the scanned images has better image quality comprises logic configured to analyze the scanned images with an image processing algorithm.

15. The computer program of claim 13, wherein the logic configured to determine which of the scanned images has better image quality comprises logic configured to determine at least one of a sharpness parameter and a contrast parameter for each scanned image.

16. The computer program of claim 13, wherein the logic configured to determine which of the scanned images has better image quality comprises:
logic configured to display both scanned images to a user; and
logic configured to receive a user selection of one of the scanned images.
